(19) United States
(12) Patent Application Publication
(10) Pub. No.: US 2008/0093595 A1
(43) Pub. Date: Apr. 24, 2008

(54) Thin film transistor for cross point memory and method of manufacturing the same

(75) Inventors: I-hun Song, Seongnam-si (KR); Young-soo Park, Yongin-si (KR); Dong-hun Kang, Yongin-si (KR); Chang-jung Kim, Yongin-si (KR); Hyuck Lim, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/976,008

(22) Filed: Oct. 19, 2007

(30) Foreign Application Priority Data
Oct. 20, 2006 (KR) 10-2006-0102464

(51) Int. Cl. H01L 29/24; H01L 21/34

(52) U.S. Cl. 257/43; 438/104; 257/E29.1; 257/E21.46

(57) ABSTRACT

A thin film transistor used as a selection transistor for a three-dimensional stacking cross point memory and a method of manufacturing the thin film transistor are provided. The thin film transistor includes a substrate, a gate, a gate insulation layer, a channel, a source and a drain. The gate may be formed on a portion of the substrate. The gate insulation layer may be formed on the substrate and the gate. The channel includes ZnO and may be formed on the gate insulation layer over the gate. The source and the drain contact sides of the channel.

### PRIORITY STATEMENT

This application claims the benefit of priority under 35 U.S.C. §119 from Korean Patent Application No. 10-2006-0102464, filed on Oct. 20, 2006, in the Korean Intellectual Property Office, the disclosure of which is incorporated herein in its entirety by reference.

### BACKGROUND

1. Field

Example embodiments relate to a thin film transistor for a cross point memory. Other example embodiments relate to a zinc oxide (ZnO) thin film transistor used as a selection transistor for a three-dimensional stacking cross point memory and a method of manufacturing the ZnO thin film transistor.

2. Description of the Related Art

As seen with recent advancements in high-density memories, a unit structure (e.g., a unit cell structure) has been developed with a three-dimensional structure. As the physical plane scaling limits have been reached for a NAND flash memory, research on a method of manufacturing a three-dimensional high-density memory has increased.

Recently, three-dimensional stacking high-density memories (e.g., memories having a cross point memory array structure with multi-stacking layers) have been actively studied. By stacking the cells on top of one another, they are achieved higher density than single-plane devices. A selection transistor used for selecting a specific layer is necessary in order to drive a three-dimensional stacking memory array. The structure each stacking layer with the low and column selection transistors has much more merits than that of the via contact from base plane. A conventional silicon (Si) complementary metal-oxide semiconductor (CMOS) transistor is difficult to use as a selection transistor each layer due to high temperature process for epi-growth in a stacking structure memory array, as will now be described in detail with reference to FIGS. 1A and 1B.

FIG. 1A is a diagram illustrating a schematic perspective view a three-dimensional stacking structure of a conventional cross point memory.

Referring to FIG. 1A, a unit cell includes a lower electrode 11, a diode structure 12, and a memory node 13 that are sequentially stacked. An upper electrode 14 may be formed on the memory node 13. In the conventional cross point memory array structure, the lower electrode 11 and the upper electrode 14 cross each other. The memory node 13 may be formed at an intersection point. The memory node 13 may be formed from a resistive material. The structure shown in FIG. 1A has as a 1diode-1resist (1D-1R) structure.

In the cross point memory array structure illustrated in FIG. 1A, the lower electrode 11 and/or the upper electrode 14 may be connected with a selection transistor 15. The selection transistor 15 selects a specific unit cell in order to read information from, or write information to, the unit cell. The number of the selection transistors 15 may be equal to the number of word lines connected to cell array rows.

FIG. 1B is a diagram illustrating a cross sectional view of a conventional stacking structure with selection transistors on each level.

Referring to FIG. 1B, a source 102a and a drain 102b may be formed in a silicon substrate 101. A gate structure may be formed between the source 102a and the drain 102b. The gate structure includes a gate insulation layer 103 and a gate electrode layer 104. It may be difficult to grow connection layers 105a and 105b by epi-growth to form a selection transistor array in correspondence with each level of the multi-layer cross point memory array structure as shown in FIG. 1A. If a lower layer is connected with an upper layer through a via hole to manufacture a multi-layer selection transistor array, the peri-circuit area increases several times, decreasing the high-density effect by the multi-layer structure.

### SUMMARY

Example embodiments relate to a thin film transistor for a three-dimensional stacking cross point memory. Other example embodiments relate to a ZnO thin film transistor used as a selection transistor for a three-dimensional stacking cross point memory and a method of manufacturing the ZnO thin film transistor.

Example embodiments relate to a thin film transistor for a cross point memory suitable for a multi-layer structure and memory integration and a method of manufacturing the thin film transistor.

According to example embodiments, there is provided a thin film transistor used as a selection transistor for a three-dimensional stacking cross point memory. The thin film transistor may include a substrate, a gate formed on a portion of the substrate, a gate insulation layer formed on the substrate and the gate, a channel including ZnO and formed on the gate insulation layer in correspondence with (or over) the gate and a source and a drain contacting sides (e.g., opposing sides) of the channel.

The channel may be formed of a compound including ZnO and at least one selected from the group consisting of gallium (Ga), indium (In), tin (Sn), aluminum (Al) and combinations thereof. The channel may have a thickness ranging from 20 nm to 200 nm.

The source or the drain may be formed of a metal or a conductive oxide. The conductive oxide may be formed of molybdenum (Mo), indium-zinc oxide (IZO or InZnO) and combinations thereof.

According to example embodiments, there is provided a method of manufacturing a thin film transistor used as a selection transistor for a three-dimensional stacking cross point memory. The method may include forming a gate by depositing a conductive material on a portion of a substrate and patterning the deposited conductive material, depositing (or forming) a gate insulation layer on the substrate and the gate, forming a channel on a portion of the gate insulation layer corresponding to the gate by depositing a channel material including ZnO on the gate insulation layer, patterning the deposited channel material, forming a source and a drain contacting sides (e.g., opposing sides) of the channel by depositing a conductive material on the channel and the gate insulation layer and patterning the conductive material.

The channel may be formed by sputtering using a compound-target including ZnO and at least one selected from the group consisting of Ga, In, Sn, Al and combinations thereof.

The channel may be formed by co-sputtering using ZnO and at least one selected from the group consisting of Ga, In, Sn, Al and combinations thereof as targets.

### BRIEF DESCRIPTION OF THE DRAWINGS

Example embodiments will be more clearly understood from the following detailed description taken into conjunction with the accompanying drawings. FIGS. 1-5 represent non-limiting, example embodiments as described herein.

FIG. 1A is a diagram illustrating a schematic perspective view of an three-dimensional stacking structure of a conventional cross point memory;

FIG. 1B is a diagram illustrating a cross sectional view of a conventional stacking structure with selection transistors.

FIG. 2 is a diagram illustrating a cross sectional view of a thin film transistor for a cross point memory according to example embodiments;

FIGS. 3A through 3E are diagrams illustrating views of a method of manufacturing a thin film transistor for a cross point memory according to example embodiments;

FIG. 4 is a graph of drain current (Id) versus gate voltage (V_{g}) for various source-drain voltages to show performance test results of a thin film transistor of a cross point memory according to example embodiments; and

FIG. 5 is a graph of drain current versus drain voltage of a thin film transistor for a cross point memory according to example embodiments.

### DETAILED DESCRIPTION OF EXAMPLE EMBODIMENTS

Various example embodiments will now be described more fully with reference to the accompanying drawings in which some example embodiments are shown. In the drawings, the thickness of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to a thin film transistor for a cross point memory. Other example embodiments relate to a zinc oxide (ZnO) thin film transistor used as a selection transistor for a cross point memory and a method of manufacturing the ZnO thin film transistor.

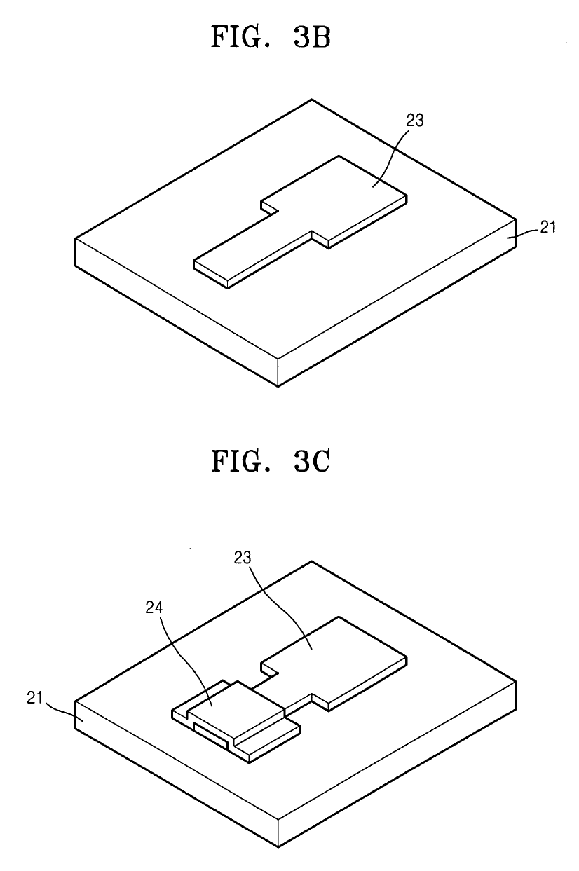

FIG. 2 is a diagram illustrating a cross sectional view of a thin film transistor for a cross point memory according to example embodiments. A bottom gate thin film transistor 20 is illustrated in FIG. 2. However, example embodiments are not limited thereto.

Referring to FIG. 2, the bottom gate thin film transistor 20 includes a substrate 21, a gate 23 and a gate insulation layer 24. An insulation layer 22 may be formed on the substrate 21. The gate 23 may be formed a portion of the substrate 21. The gate insulation layer 24 may be formed on the substrate 21 and the gate 23. A channel 25 may be formed on the gate insulation layer 24 corresponding to the gate 23. A source 26A and a drain 26B may be formed on sides (e.g., opposing) of the channel 25 and the gate insulation layer 24. The source 26A and a drain 26B may be formed on portions of sides (e.g., opposing) of the channel 25 and the gate insulation layer 25.

The substrate 21 may be a silicon (Si) substrate. The insulation layer 22 formed on the substrate 21 may be a thermal oxide layer. The thermal oxide layer may be formed by thermally oxidizing the Si substrate. The thickness of the insulation layer 22 may be smaller than 100 nm. The gate insulation layer 24 may be formed using an insulation material known in the art. A high-k dielectric material (e.g., silicon nitride (Si₃N₄)) may be used for the gate insulation layer 24. The permittivity of the high-k dielectric material may be higher than that of silicon oxide (SiO₂). The thickness of the gate insulation layer 24 may be smaller than 200 nm. The channel 25 may be formed using a compound thin film. The compound thin film may be formed by adding a different metal (e.g., Ga, In, Sn, Al or combinations thereof) to ZnO. The thickness of the channel 25 may range from 20 nm to 200 nm. The source 26A and the drain 26B may be formed using a metal (e.g., Mo, Al, W, Cu or combinations thereof) or a conductive oxide (e.g., IZO (InZnO), AZO (AlZnO) or combinations thereof). The thicknesses of the source 26A and the drain 26B may be smaller than 100 nm.

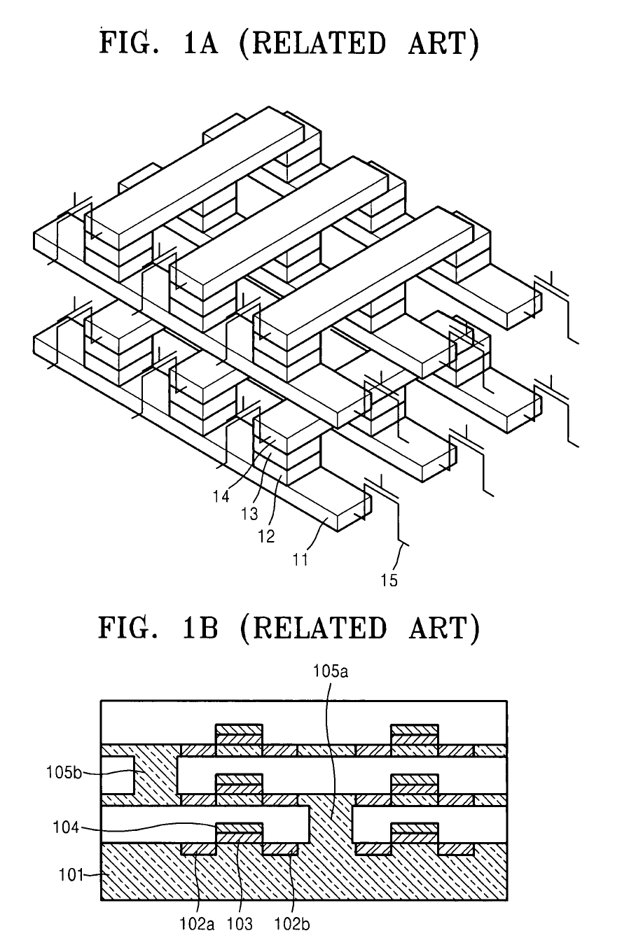

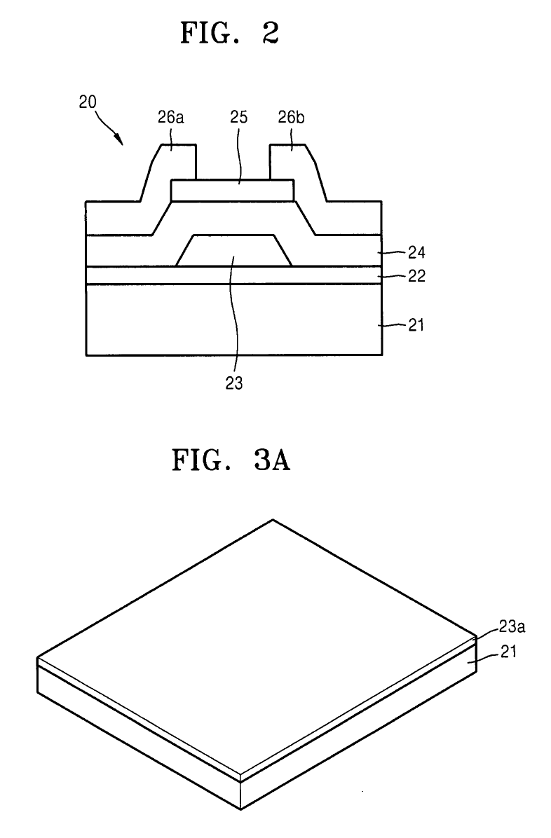

The thin film transistor illustrated in FIG. 2 according to example embodiments may be used as the selection transistor for the cross point memory shown in FIG. 1A. In this case, the thin film transistor may be formed in correspondence with each word line of the cross point memory.

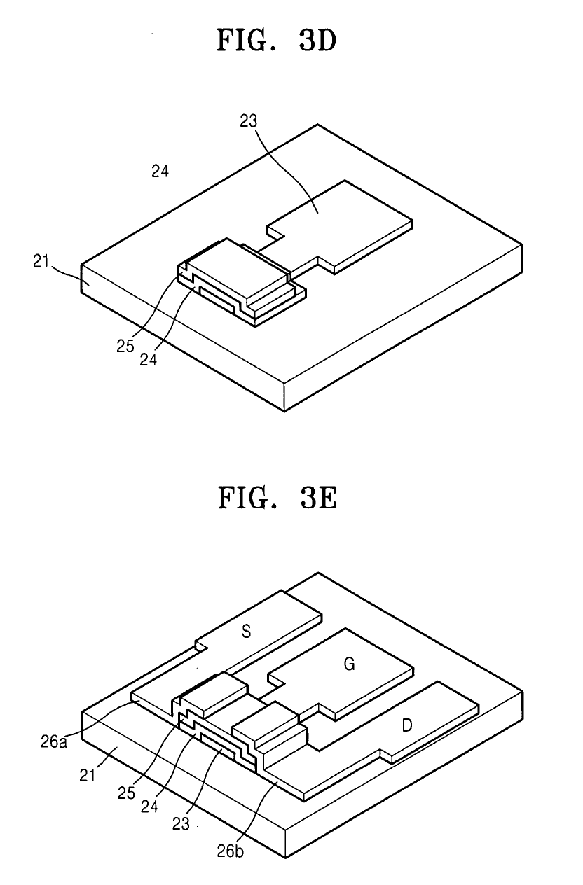

A method of manufacturing a thin film transistor for a cross point memory will now be described in detail with reference to FIGS. 3A through 3E according to example embodiments.

Referring to FIG. 3A, an insulation layer (not shown) may be formed on a substrate 21. A conductive material 23a (e.g., Mo) may be deposited on the substrate 21 using sputtering or the like.

Referring to FIG. 3B, a gate 23 may be formed by patterning the conductive material 23a.

Referring to FIG. 3C, a gate insulation layer 24 may be formed by depositing an insulation material (e.g., SiO₂ or Si₃N₄) on the gate 23 and patterning the deposited insulation material. The insulation material may be deposited using a deposition method (e.g., plasma-enhanced chemical vapor deposition (PECVD)).

Referring to FIG. 3D, a channel 25 may be formed by depositing a channel material on the gate insulation layer 24. The channel material may be a compound formed by adding a metal (e.g., Ga, In, Sn, Al or combination thereof) to ZnO as described above. For example, a compound of Ga₂O₃, In₂O₃, and ZnO may be used.

In a deposition process using sputtering, a metal compound including zinc (Zn) and at least one selected from the group consisting of Ga, In, Sn, Al and combinations thereof may be used as a single target. Co-sputtering may be possible using ZnO and at least one selected from the group consisting of Ga, In, Sn, Al and combinations thereof as targets. For example, if a single target is used in a sputtering process, a compound including Ga₂O₃, In₂O₃ and ZnO may be used as the single target. Ga₂O₃, In₂O₃ and ZnO may be present in a ratio of 2:2:1.

Referring to FIG. 3E, a source 26a and a drain 26b may be formed by depositing a conductive material on the channel 25 and the substrate 21 and patterning the conductive material. The source 26a and the drain 26b may each overlap with the channel 25 at the respective side of the channel 25.

The resulting stacked structure, which includes the channel 25 and the source 26a and drain 26b contacting sides of the channel 25, may be heat treated at a temperature below 400° C. (e.g., at 300° C.). The heat treatment may be performed in the presence of nitrogen (N₂) using a furnace, a rapid thermal annealing (RTA) apparatus, a laser, a hot plate or the like. The contact surfaces between the channel 25 and the source 26A and between the channel 25 and the drain 26B may be stabilized by the heat treatment.

To manufacture a multi-layer selection transistor array, the above-described operations may be repeated. That is, an insulation material may be formed on the stacked structure including the channel 25, the source 26a, and drain 26b. The gate electrode process illustrated in FIGS. 3A-3E may be performed.

Unlike a conventional method of manufacturing a Si CMOS transistor, the method of manufacturing the thin film transistor according to example embodiments does not require connection layers for Si epi-growth. Because injecting a dopant is not necessary to form the source 26a and the drain 26b, a high-temperature heat treatment is not necessary for activating the source 26a and the drain 26b. As such, memory device stability of the memory device may increase due to the low-temperature (below 400° C.) heat treatment.

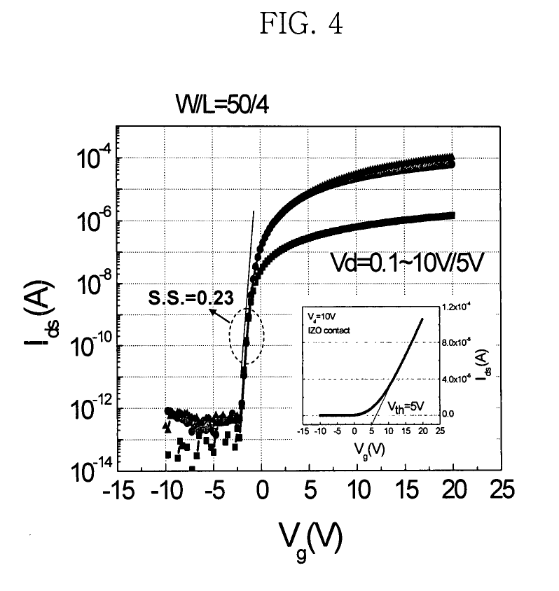

FIG. 4 is a graph of drain current (Id) versus gate voltage (V_{g}) for various source-drain voltages to show performance test results of a thin film transistor of a cross point memory according to example embodiments. For the performance test of FIG. 4, a 200-nm molybdenum gate and a 70-nm channel formed by sputtering using a target including Ga₂O₃, In₂O₃ and ZnO (2:2:1) was used.

Referring to FIG. 4, the on-state current is 10⁻⁴ A and the off-state current is below 10⁻¹² A. The current ratio of on-state to off-state is larger than 10⁸. The on/off current ratio is high. The off-state current is low. The channel mobility is 10 cm²/Vs. The gate swing voltage is 0.23 V/dec. Hysteresis does not occur. As such, the thin film transistor according to example embodiments have be used as a selection transistor for a cross point memory.

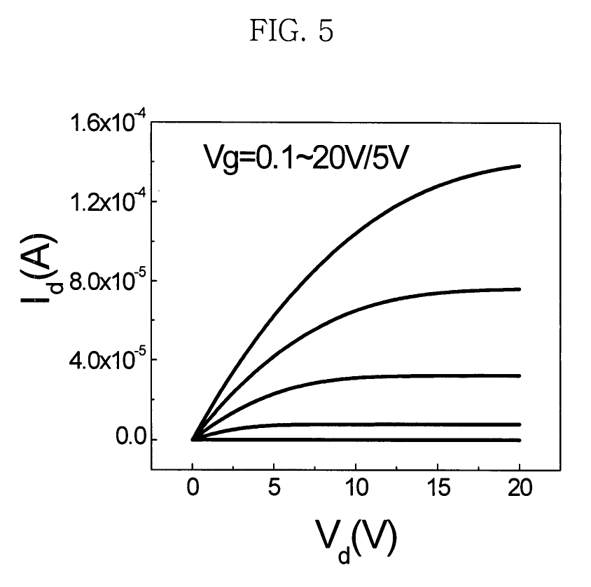

FIG. 5 is a graph of the drain current versus the drain voltage at various gate voltages of a thin film transistor for a cross point memory according to example embodiments.

Referring to FIG. 5, the drain current is constant regardless of the drain voltage if the gate voltage is applied at 0.1 V. If the gate voltage is larger than 5 V, then the drain current gradually increases in proportion (or relation) to the drain voltage.

According to example embodiments, the compound thin film including ZnO used as a channel does not need a substantially high temperature process. Because the dopant injection process is not necessary for forming the source and the drain, a high temperature heat treatment is not necessary for activating the source and the drain. As such, the thin film transistor may be easily manufactured without any property changes.

In the method of manufacturing a thin film transistor for a cross point memory according to example embodiments, connection layers are not required for Si epi-growth and an upper thin film transistor may be formed on a lower thin film transistor after depositing an insulation material on a source and a drain of the lower thin film transistor, unlike a conventional method of manufacturing a Si CMOS transistor. As such, a selection transistor array may be easily manufactured.

Because the thin film transistor for the cross point memory has the desired mobility and on/off current characteristics without hysteresis, the transistor may be more appropriate for use as a selection transistor.

Because the cross point memory having a 1D-1R three-dimension structure may be driven independently per each layer of the memory, a peri-circuit structure may be less complex and a high-density structure may be easier to attain.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A thin film transistor, comprising:
a gate on a portion of a substrate;
a gate insulation layer on the substrate and the gate;
a channel including zinc oxide (ZnO) on the gate insulation layer over the gate; and
a source and a drain contacting opposing sides of the channel,
wherein the thin film transistor is used as a selection transistor for a three-dimensional stacking cross point memory.

2. The thin film transistor of claim 1, wherein the channel is formed of a compound including ZnO and at least one selected from the group consisting of gallium (Ga), indium (In), tin (Sn), aluminum (Al) and combinations thereof.

3. The thin film transistor of claim 2, wherein the compound is formed of gallium oxide (Ga₂O₃), indium oxide (In₂O₃) and ZnO.

4. The thin film transistor of claim 1, wherein the source is formed of a metal or a conductive oxide.

5. The thin film transistor of claim 4, wherein the metal is at least one selected from the group consisting of molybdenum (Mo), aluminum (Al), tungsten (W), copper (Cu) and combinations thereof, and
the conductive oxide is at least one selected from the group consisting of indium-zinc oxide (IZO or InZnO), aluminum-zinc oxide (AZO or AlZnO) and combinations thereof.

6. The thin film transistor of claim 1, wherein the drain is formed of a metal or a conductive oxide.

7. The thin film transistor of claim 6, wherein the metal is at least one selected from the group consisting of molybdenum (Mo), aluminum (Al), tungsten (W), copper (Cu) and combinations thereof, and
the conductive oxide is at least one selected from the group consisting of indium-zinc oxide (IZO or InZnO), aluminum-zinc oxide (AZO or AlZnO) and combinations thereof.

8. The thin film transistor of claim 1, wherein the channel has a thickness of 20 nm to 200 nm.

9. A method of manufacturing a thin film transistor, comprising:
forming a gate by depositing a conductive material on a portion of a substrate and patterning the deposited conductive material;
depositing a gate insulation layer on the substrate and the gate;
forming a channel on a portion of the gate insulation layer over the gate by depositing a channel material including zinc oxide (ZnO) on the gate insulation layer and patterning the deposited channel material; and
forming a source and a drain contacting opposing sides of the channel by depositing a conductive material on the channel and the gate insulation layer and patterning the conductive material,
wherein the thin film transistor is used as a selection transistor for a three-dimensional stacking cross point memory.

10. The method of claim 9, wherein the channel is formed by sputtering using a compound-target including ZnO and at least one selected from the group consisting of gallium (Ga), indium (In), tin (Sn), aluminum (Al) and combinations thereof.

11. The method of claim 10, wherein the compound-target includes gallium oxide (Ga₂O₃), indium oxide (In₂O₃) and ZnO.

12. The method of claim 9, wherein the channel is formed by co-sputtering using ZnO and at least one selected from the group consisting of gallium (Ga), indium (In), tin (Sn), aluminum (Al) and combinations thereof as targets.

13. The method of claim 9, wherein the source is a metal or a conductive oxide.

14. The thin film transistor of claim 13, wherein the metal is at least one selected from the group consisting of molybdenum (Mo), aluminum (Al), tungsten (W), copper (Cu) and combinations thereof, and
the conductive oxide is at least one selected from the group consisting of indium-zinc oxide (IZO or InZnO), aluminum-zinc oxide (AZO or AlZnO) and combinations thereof.

15. The thin film transistor of claim 9, wherein the drain is formed of a metal or a conductive oxide.

16. The thin film transistor of claim 15, wherein the metal is at least one selected from the group consisting of molybdenum (Mo), aluminum (Al), tungsten (W), copper (Cu) and combinations thereof, and
the conductive oxide is at least one selected from the group consisting of indium-zinc oxide (IZO or InZnO), aluminum-zinc oxide (AZO or AlZnO) and combinations thereof.

17. The method of claim 10, wherein the channel has a thickness of 20 nm to 200 nm.
